(19) United States
(12) Patent Application Publication
(10) Pub. No.: US 2006/0232328 A1
(43) Pub. Date: Oct. 19, 2006

(54) Switchable low pass configuration and an optical receiver with a switchable low pass configuration

(76) Inventor: Ing. Karl Schrödinger, Berlin (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/104,708

(22) Filed: Apr. 13, 2005

(51) Int. Cl. H03K 5/00

(52) U.S. Cl. 327/552

(57) ABSTRACT

The invention relates to a switchable low-pass filter arrangement which has an upper limiting frequency determining the low-pass filter behavior. The arrangement includes a transistor circuit, which has at least one transistor arranged as a source follower or as an emitter follower; a capacitive component at the output of the transistor circuit; and a programmable device for setting the operating current of the transistor circuit. In this case, the limiting frequency of the low-pass filter arrangement is switchable by means of the programmable device for setting the operating current of the transistor circuit. This creates a switchable low-pass filter arrangement which does not have any changeover switches in the signal path, is suitable for radiofrequency applications and can be produced in a simple manner. The invention furthermore relates to an optical receiver having a low-pass filter arrangement of this type.

The invention relates to a switchable low-pass filter arrangement having a capacitive component, which does not require any changeover switches in the signal path and which is thus suitable for radiofrequency applications in optical receivers. The invention furthermore relates to an optical receiver having a low-pass filter arrangement of this type.

### BACKGROUND OF THE INVENTION

Switchable low-pass filter arrangements are known which are constructed as electrical circuits by means of resistors and capacitors and which may be designed as simple RC elements. Such RC elements have a resistor in series with an input and a capacitor in parallel with an output of the arrangement. The low-pass filter behavior of such arrangements is described by an upper limiting frequency determined by the values of the resistor and of the capacitor. Signals below said limiting frequency which are present at the low-pass filter arrangement are not substantially influenced and are transmitted unchanged, but signals above the limiting frequency are attenuated and thus largely suppressed.

For switching of such low-pass filter arrangements, the resistor of the circuit may be designed to be switchable by means of changeover switches that are arranged in the signal path of the arrangement in series with the resistor. The changeover switches may be produced for example by means of field effect transistors using MOS technology. What is disadvantageous about such arrangements is that the changeover switches act in the signal path and thus influence the signal, represent an additional series resistance, which brings about ohmic losses, and have parasitic capacitances, in particular with the use of field effect transistors using MOS technology. In this case, the parasitic capacitances of the changeover switches are disadvantageous in particular for applications in the radiofrequency range since these are transmissive for high frequencies, thus bridge the changeover switch and consequently make the low-pass filter arrangements unsuitable for applications in the gigahertz range.

Therefore, there is a need for switchable low-pass filter arrangements, in particular for optical receivers, which do not have any changeover switches in the signal path, are suitable for radiofrequency applications, have low losses and can be produced in a simple manner.

### SUMMARY OF THE INVENTION

The invention provides a switchable low-pass filter arrangement which has an upper limiting frequency determining the low-pass filter behavior of the arrangement, having
a transistor circuit, which has at least one transistor arranged as a source follower or as an emitter follower,
a capacitive component at the output of the transistor circuit, and
a programmable device for setting the operating current of the transistor circuit.

In this case, the limiting frequency of the low-pass filter arrangement is switchable by means of the programmable device for setting the operating current of the transistor circuit.

The invention is thus based on the concept of using the transistor circuit designed as a source follower or an emitter follower together with a capacitive component for example in the form of a capacitor as a low-pass filter arrangement and setting the limiting frequency of the low-pass filter arrangement by setting the operating current of the transistor circuit. The operating current of the transistor circuit is set by means of the programmable device, which is designed in such a way that it has different, switchable states which in each case bring about a different operating current, so that the operating current can be set and hence the limiting frequency of the low-pass filter arrangement can be switched by means of the state of the device. The low-pass filter arrangement according to the invention utilizes the behavior of the transistor circuit which is designed as a source follower or emitter follower and the output resistance of which interacts with the capacitive component in such a way that the arrangement has a low-pass filter characteristic similar to an RC element, the output resistance of the transistor circuit and thus the low-pass filter characteristic of the arrangement being variable by means of the setting of the operating currents, that is to say the setting of the operating point of the transistor circuit.

The changeover between different limiting frequencies is effected by means of the programmable device for setting the operating current, that is to say the operating point of the transistor circuit, which, in principle, may be designed like a switchable current source and thus defines the operating point, sets the output resistance of the transistor circuit and hence determines the limiting frequency of the low-pass filter arrangement.

The low-pass filter arrangement can be interpreted as a switchable RC element, in which case, with the low-pass filter arrangement according to the invention, there is no need for any changeover switches for switching components in the signal path, losses are reduced and the parasitic capacitances taking effect in the signal path are reduced. The low-pass filter arrangement according to the invention is thus also suitable for radiofrequency applications in the gigahertz range, for example as a switchable low-pass filter for an optical receiver with variable data rates.

The device for setting the operating current preferably contains an additional transistor which is fed by means of a switchable voltage source and thus acts like a switchable current source. The transistor is connected to the transistor circuit designed as a source follower or emitter follower and thus sets the operating currents of the transistor circuit.

The device for setting the operating current is preferably designed as a programmable current mirror which, in its simplest embodiment, has two transistors that can be coupled with negative feedback by resistors, and which is switchable by means of a reference resistor. Such programmable current mirrors act as a current source that sets the operating current and thus defines the operating point of the transistor arranged as a source follower or emitter follower.

In an advantageous variant, the device for setting the operating current of the transistor circuit comprises a constant-gm circuit that compensates for temperature influences by keeping the transconductance of a reference transistor constant. The functioning of a constant-gm circuit is known from the literature (see for example in T. Lee, “The design of CMOS radiofrequency integrated circuits”, Cambridge University Press, 1998, pages 235-237). The constant-gm circuit makes it possible, in a simple manner, to achieve an operating behavior of the low-pass filter arrangement that is stable, in particular is independent of temperature influences.

The device preferably has means for generating different switching states which in each case bring about a different operating current. For this purpose, the constant-gm circuit may have a reference resistor, which determines the transconductance of a reference transistor and generates a constant reference voltage at an output of the circuit, which reference voltage controls the current mirror and brings about a constant operating current of the transistor circuit of the low-pass filter arrangement. The reference resistor of the constant-gm circuit is preferably of switchable design in order, in this way, to set the operating currents of the low-pass filter arrangement in a variable manner and to alter the limiting frequency of the low-pass filter arrangement.

In one variant, the low-pass filter arrangement may be used in combination with an amplifier circuit which, by way of example, is part of an optical receiver and is designed for radiofrequency signals, and said arrangement may be connected downstream of said amplifier circuit for the filtering of the signal. In a further variant, the low-pass filter arrangement is used in combination with a differential amplifier circuit, a low-pass filter arrangement in each case being connected to an output of the differential amplifier circuit. The output signal of the differential amplifier circuit filtered by means of the low-pass filter arrangement is then present as a differential signal at the outputs of the low-pass filter arrangements connected to the amplifier circuit.

The invention furthermore relates to an optical receiver having a switchable low-pass filter arrangement having the features mentioned. In this case, the low-pass filter arrangement may be connected downstream of an amplifier circuit of the optical receiver, which is part of the optical receiver. In this case, the low-pass filter arrangement is preferably connected to a differential amplifier circuit in order to filter the output signal of the differential amplifier circuit.

### BRIEF DESCRIPTION OF THE DRAWINGS

The concept on which the invention is based will be explained in more detail below on the basis of a plurality of exemplary embodiments with reference the figures, in which:

FIG. 1 shows a circuit diagram of a switchable low-pass filter arrangement in accordance with the prior art that is designed as an RC element;

FIG. 2 shows a circuit diagram of a switchable low-pass filter arrangement with a transistor arranged as a source follower;

FIG. 3 shows a circuit diagram of a switchable constant-gm circuit with a programmable reference resistor arrangement, and

FIG. 4 shows a circuit diagram of a differential amplifier circuit with low-pass filter arrangements connected downstream.

### DETAILED DESCRIPTION OF THE EXEMPLARY EMBODIMENTS

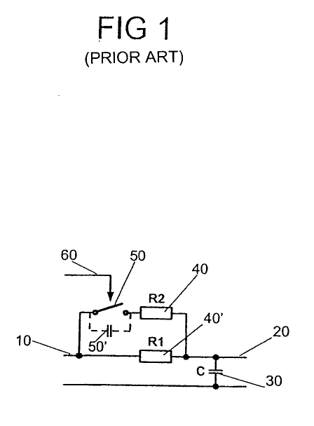

FIG. 1 shows a switchable low-pass filter arrangement known in accordance with the prior art, which arrangement has parallel-connected resistors 40, 40′ and a capacitor 30. The arrangement filters a signal that is present at the input 10 and is transmitted to the output 20, in such a way that the low-frequency components of the signal are not influenced, but the high-frequency components are attenuated. The limiting frequency between non-influenced low-frequency and attenuated high-frequency signal components is defined as the frequency at which the arrangement effects a signal attenuation of 3 dB, and is determined by the resistance of the resistor combination 40, 40′ in the signal path and the capacitance of the capacitor 30.

Situated in the path of the resistor 40 is a changeover switch 50, which is switched by means of a switching signal 60 and DC-isolates the resistor 40 from the circuit and thus renders it inactive. As a result of the changeover of the switch 50, the resistance that takes effect in the signal path is altered and the limiting frequency of the arrangement is thus shifted.

The changeover switch 50 may be realized by using transistor components, such as, for example, field effect transistors produced using MOS technology. Since the changeover switch 50 is arranged in the signal path of the arrangement in series with the input 10 of the arrangement, the transistor components of the changeover switch 50, which have a series resistance and a parasitic capacitance 50′, act directly in the signal path and adversely influence the signal. The parasitic capacitance 50′, in particular, acts like a short circuit at radiofrequency signals, thus bridges the changeover switch 50 and brings about a behavior of the combination comprising changeover switch 50 and resistor 40 that is similar to a high-pass filter. For radiofrequency applications, it is furthermore necessary to use a low-resistance changeover switch 50, which can only be realized by means of large-area transistors which, however, have a large parasitic capacitance 50′ and thus make the arrangement unsuitable for radiofrequency applications.

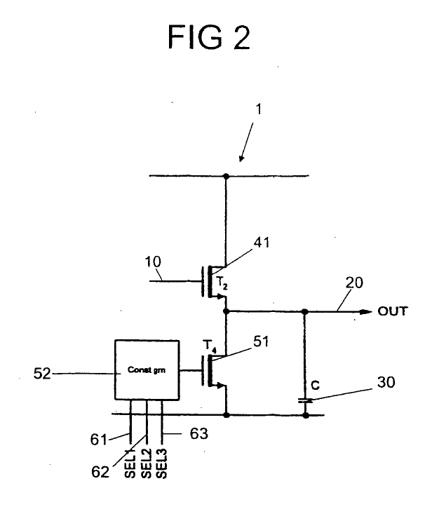

FIG. 2 shows a low-pass filter arrangement 1 having a MOS field effect transistor (MOSFET) 41 arranged as a source follower and a capacitor 30 forming a capacitive component. Gate and source of the MOSFET represent the input 10 and the output 20 of the low-pass filter arrangement 1, the capacitor 30 being arranged between the output 20 and a ground line. The operating currents of the MOSFET are set by means of a second MOSFET 51 and a constant-gm circuit 52.

The low-pass filter arrangement 1 illustrated in FIG. 2 may likewise have, instead of the MOSFET 41 designed as a source follower, a bipolar transistor arranged as an emitter follower without the arrangement behaving differently in principle. The low-pass filter arrangement 1 is often part of an integrated semiconductor circuit which has a multiplicity of electronic assemblies and is produced using a specific technology, so that the technology used for the underlying application decides what design is to be used for the low-pass filter arrangement. For a circuit using MOS technology, by way of example, a MOSFET 41 arranged as a source follower is advantageously used, as in the low-pass filter arrangement in FIG. 2. However, the fundamental functioning of the low-pass filter arrangement is independent of whether source followers or emitter followers are used.

Transistor circuits designed as a source follower or as an emitter follower are known and described extensively in the literature (see for example U. Tietze, Ch. Schenk, “Halbleiter-Schaltungstechnik”, [Semiconductor Circuitry], Springer Verlag, 11th Edition 1999). The input signal is present at the gate of the field effect transistor in the case of the source follower and at the base of the bipolar transistor in the case of the emitter follower, while the output signal is tapped off on the source side in the case of the source follower and on the emitter side in the case of the emitter follower. In both cases, the output impedance Rₒᵤₜ of the circuit is determined by the transconductance of the transistor used and corresponds to the reciprocal of the transconductance gₘ:

$${R}_{out} = \frac{1}{{g}_{m}} . \qquad ( 1 )$$

In the case of a field effect transistor using MOS technology, on the one hand, the transconductance of the transistor is given by

$${g}_{m} = \sqrt{2 {μ}_{n} {C}_{ox} \frac{W}{L} {I}_{D}} , \qquad ( 2 )$$

where μₙ denotes the charge carrier mobility (in this case for an n-chanel transistor), Cₒₓ denotes the oxide capacitance, W/L denotes the width-to-length ratio of the transistor and I_{d} denotes the drain current I_{d} of the MOSFET. All quantities with the exception of the drain current I_{d} in (2) are constant parameters predetermined by the geometry and the material of the transistor. In this case, the charge carrier mobility μₙ is temperature-dependent but can be kept constant by means of the constant-gm circuit 52, by means of which the operating current is set.

In the case of a bipolar transistor, on the other hand, the transconductance is defined by

$${g}_{m} = \frac{{eI}_{C}}{kT} , \qquad ( 3 )$$

where e designates the elementary charge, k designates the Boltzmann constant and T designates the temperature and I_{c} denotes the collector current.

In the case of the low-pass filter arrangement 1 illustrated in FIG. 2, the output impedance of the transistor 41 arranged as a source follower, together with the capacitor 30—arranged at the output 20 of the circuit—with the capacitance Cₒᵤₜ, determines the limiting frequency f_{3dB} of the low-pass filter arrangement 1, which is given by

$${f}_{3 dB} = \frac{1}{2 π {R}_{out} {C}_{out}} = \frac{{g}_{m}}{2 π {C}_{out}} . \qquad ( 4 )$$

Consequently, the limiting frequency of the low-pass filter arrangement 1 can be set by setting the operating current by means of the transconductance of the transistor 41 in accordance with equation (2). In the case of a low-pass filter arrangement 1 with a bipolar transistor arranged as an emitter follower, the setting is effected analogously in accordance with equation (3).

The operating point is set by means of the setting of the operating current, which is switchable but exhibits static behavior between the switching intervals. A radiofrequency signal present at the input 10 of the low-pass filter arrangement 1 must have an amplitude which is small in comparison with the magnitude of the operating current set, so that the signal present does not alter the operating point of the transistor 41. The signal behavior of the low-pass filter arrangement 1 can then be described by means of the so-called small-signal behavior of the transistor 41.

The operating currents are set, in the case of the low-pass filter arrangement illustrated in FIG. 2, by means of a MOSFET 51 connected to the source terminal of the transistor 41 arranged as a source follower. The transistor 51, together with the constant-gm circuit 52, serves as a bias circuit for the transistor 41 arranged as a source follower, acts like a current source and thus defines the operating point and hence also the drain current of the transistor 41.

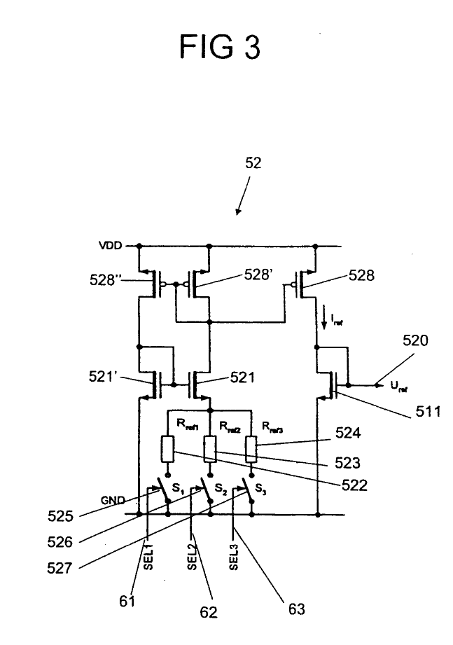

The circuit diagram of the constant-gm circuit 52 is shown in FIG. 3. The method of operation of the constant-gm circuit 52 in detail is described for example in T. Lee, “The design of CMOS radiofrequency integrated circuits”, Cambridge University Press, 1998, pages 235-237. The constant-gm circuit 52 has a stabilizing effect and compensates for temperature influences by keeping the transconductance of a reference transistor 521′ constant, and, by means of the current mirrors 528, 528′, 528″, 511, 51, stabilizing the transconductance of the transistor 41 arranged as a source follower and thus keeping the limiting frequency of the low-pass filter arrangement 1 constant. The transconductance of the reference transistor 521′ is set by means of a reference resistor or a reference resistor arrangement having resistors 522-524, which is connected to a transistor 521 forming a current mirror together with the reference transistor 521′, and corresponds to the reciprocal of the resistance of the reference resistor arrangement 522-524, which is switchable by means of the control lines 61-63 and the changeover switches 525-527. In this case, the transistor 521 is dimensioned to be very large, so that its effective resistance is small and the current through the transistor 521 is essentially defined by the resistors 522-524. The reference current I_{ref} set by means of the current mirror 528, 528′, 528″ serves as the drain current of the transistor 511 and thus brings about a reference voltage U_{ref} at the gate terminal of the transistor 511 which sets a constant transconductance of the transistor 41.

Improved circuit variants of the constant-gm circuit are possible and are described in detail in T. Lee, “The design of CMOS radiofrequency integrated circuits”, Cambridge University Press, 1998, pages 235-237.

The constant-gm circuit 52 is connected via the output 520 to the gate of the transistor 51 in the source path of the low-pass filter arrangement 1 and provides a reference voltage U_{ref} at the output 520 of the constant-gm circuit which sets a constant transconductance of the transistor 41. The transistor in the source path of the low-pass filter arrangement 1 acts together with the transistor 511 like a current mirror which is controlled by means of the reference voltage U_{ref} and sets the drain current of the transistor 41 designed as a source follower such that the transconductance is constant independently of temperature influences. The reference voltage controlling the current mirror 51, 511 is switchable and variable by means of the switchable reference resistor arrangement 522-524. Depending on the set resistance of the reference resistor arrangement 522-524, the current mirror sets the operating current of the low-pass filter arrangement 1, which is thus switchable by means of the reference resistor arrangement 522-524.

The constant-gm circuit 52 makes it possible, with simple means, to produce a temperature-stable, switchable device for setting the operating currents of the low-pass filter arrangement 1. Since the changeover switches 525-527 used for switching the reference resistor arrangement 522-524 are not situated in the signal path of the low-pass filter arrangement 1, they have no effects on the signal and the parasitic losses brought about by the changeover switches 525-527 are negligible.

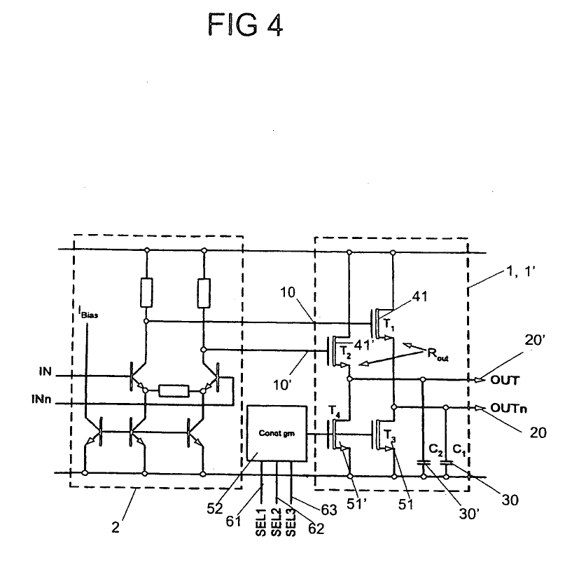

FIG. 4 shows a circuit diagram of a differential amplifier arrangement 2, to the output paths of which is connected a respective low-pass filter arrangement 1, 1′ with a transistor 41, 41′ arranged as a source follower. The differential output signal of the differential amplifier is present at the two inputs 10, 10′ of the low-pass filter arrangements 1, 1′ and is tapped off as a differential output signal between the outputs 20, 20′ of the low-pass filter arrangements 1, 1′. Each low-pass filter arrangement 1, 1′ has the components described above and inherently acts in the manner described above. The limiting frequency of the two low-pass filter arrangements 1, 1′ is set by means of a constant-gm circuit 52, which is switchable by means of the control lines 61, 62, 63 and interacts with the transistors 51, 51′ and defines the operating point of the low-pass filter arrangements 1, 1′.

The low-pass filter arrangement 1, 1′ can be used in a multiplicity of integrated circuits as a switchable low-pass filter that can be produced in a simple manner. Over and above the exemplary embodiments described here, it is also possible to use the low-pass filter arrangement 1, 1′ in cascaded form for producing higher-order low-pass filters which has a plurality of transistor circuits arranged in cascaded fashion. In addition to the application in optical receivers, a multiplicity of possible uses are conceivable, such as, for example, in equalizer circuits for fiber-optic applications or in optoelectronic amplifier circuits.

1-11. (canceled)

12. A switchable low-pass filter arrangement configured to determine the low-pass filter behavior of the arrangement by an upper limiting frequency, comprising:
a transistor circuit, comprising at least one transistor arranged as a source follower, or as an emitter follower;
a capacitive component coupled to the output of the transistor circuit; and
a programmable device configured to set an operating current of the transistor circuit;
wherein the upper limiting frequency of the low-pass filter arrangement is switchable by means of the programmable device for setting the operating current of the transistor circuit.

13. The arrangement of claim 12, wherein the programmable device comprises an additional transistor fed by a switchable voltage source.

14. The arrangement of claim 12, wherein the programmable device for setting the operating current comprises a programmable current mirror.

15. The arrangement of claim 12, wherein the programmable device comprises a constant-gm circuit configured to generate the operating current that is operable to compensate for temperature influences.

16. The arrangement of claim 15, wherein the constant-gm circuit comprises switchable resistors that set the operating current of the low-pass filter arrangement.

17. The arrangement of claim 12, wherein the programmable device comprises a means for generating different switching states for setting different operating current magnitudes.

18. The arrangement of claim 12, wherein the low-pass filter arrangement is coupled to an amplifier circuit.

19. The arrangement of claim 12, wherein a low-pass filter arrangement is coupled to an output of a differential amplifier circuit.

20. A low-pass filter arrangement, comprising:
a transistor circuit, comprising a transistor arranged as a source follower or an emitter follower, wherein the transistor comprises a control terminal forming an input of the low-pass filter arrangement, and an output terminal forming an output of the low pass filter arrangement;
a capacitive component coupled to the output of the low pass filter arrangement, wherein the transistor circuit and the capacitive component cooperatively operate to substantially attenuate a signal above a limiting frequency thereof, and provide the attenuated signal at the output, wherein the limiting frequency is a function of a transconductance of the transistor circuit and a capacitance of the capacitive component; and
a bias circuit coupled to the transistor circuit, and configured to selectively vary an operating current associated with the transistor circuit, thereby altering the transconductance thereof and the limiting frequency of the low pass filter arrangement.

21. The arrangement of claim 20, wherein the bias circuit comprises a switchable current source configured to selectively set a plurality of discrete different operating currents.

22. The arrangement of claim 20, wherein the bias circuit comprises:
a transistor having a controlled path coupled to the transistor circuit and a control terminal; and
a transconductance control circuit configured to generate a control voltage at the control terminal of the transistor, wherein the control voltage is a function of a desired operating current of the transistor circuit.

23. The arrangement of claim 22, wherein the transistor is configured to generate the desired operating current based on the control voltage coupled thereto.

24. The arrangement of claim 22, wherein the transconductance of the transconductance control circuit is kept stable by means of a current mirror and thereby keeping the limiting frequency of the low-pass filter arrangement constant.

25. The arrangement of claim 24, wherein the current mirror is operable to set a reference current for a reference voltage at the control terminal of the transistor.

26. The arrangement of claim 25, wherein the transconductance control circuit comprises:
a current mirror circuit; and
a variable reference resistor arrangement, wherein at least two transistors of the current mirror circuit are coupled with negative feedback by resistors of the variable reference resistor arrangement and is switchable by the reference resistor arrangement coupled to control lines and changeover switches.

27. The arrangement of claim 24, wherein the variable reference resistor arrangement is coupled to control lines and changeover switches, wherein the changeover switches are not situated in the signal path of the low-pass filter arrangement.
